(19) United States
(12) Patent Application Publication
(10) Pub. No.: US 2024/0313019 A1
(43) Pub. Date: Sep. 19, 2024

(54) SOLID-STATE IMAGING ELEMENT AND IMAGING DEVICE

(71) Applicant: SONY SEMICONDUCTOR SOLUTIONS CORPORATION, KANAGAWA (JP)

(72) Inventor: SHINICHIRO KURIHARA, KANAGAWA (JP)

(21) Appl. No.: 18/550,994

(22) PCT Filed: Feb. 17, 2022
(86) PCT No.: PCT/JP2022/006433

§ 371 Date: Sep. 18, 2023

(30) Foreign Application Priority Data
Mar. 31, 2021 (JP) 2021-061235

(51) Int. Cl. H01L 27/146

(52) U.S. Cl. CPC H01L 27/1463; H01L 27/14621; H01L 27/14625

(57) ABSTRACT

A solid-state imaging element includes a pixel array unit in which a plurality of pixels each having a photoelectric converter is arranged in each of a row direction and a column direction, in which the pixel array unit includes an inter-pixel isolator that isolates the plurality of pixels adjacent to each other, each of the plurality of pixels includes a filter having a predetermined light transmission characteristic, the inter-pixel isolator is formed without intersecting the inter-pixel isolator, and the filter having a same light transmission characteristic is disposed between the plurality of pixels adjacent to each other.

### TECHNICAL FIELD

The present technology relates to a solid-state imaging element and an imaging device, and particularly relates to a technical field of a solid-state imaging element in which a filter having a different light transmission characteristic is disposed in a pixel, and an imaging device including such a solid-state imaging element.

### BACKGROUND ART

As a solid-state imaging element, a solid-state imaging element in which a polarizing filter having a different polarization direction (polarization axis) is disposed for every pixel has been proposed (for example, Patent Document 1). By using such a solid-state imaging element, polarization information of a subject can be acquired.

### CITATION LIST

### Patent Document

Patent Document 1: Japanese Patent Application Laid-Open No. 2017-038011

### SUMMARY OF THE INVENTION

### Problems to be Solved by the Invention

Meanwhile, in a solid-state imaging element, an inter-pixel isolator such as a trench is formed between pixels in order to reduce crosstalk between the pixels. The trench is formed, for example, by cutting a back surface of a semiconductor substrate to a predetermined depth.

However, if there is an intersecting portion at the time of forming the trench, the intersecting portion is cut deeper than other portions, and thus, a process load at the time of manufacturing increases. For example, wafer warpage is likely to occur.

The present technology has been made in view of the above circumstances, and an object of the present technology is to suppress degradation of a pixel signal while reducing a process load.

### Solutions to Problems

A solid-state imaging element of the present technology includes a pixel array unit in which a plurality of pixels each having a photoelectric converter is arranged in each of a row direction and a column direction, in which the pixel array unit includes an inter-pixel isolator that isolates the plurality of pixels adjacent to each other, each of the plurality of pixels includes a filter having a predetermined light transmission characteristic, the inter-pixel isolator is formed without intersecting the inter-pixel isolator, and the filter having the same light transmission characteristic is disposed between the plurality of pixels adjacent to each other.

As a result, even if crosstalk occurs in a portion provided with no inter-pixel isolator between pixels in which filter having the same light transmission characteristic is disposed, charges based on light transmitted through the filter having the same light transmission characteristic move.

### BRIEF DESCRIPTION OF DRAWINGS

FIG. 1 is a block diagram illustrating an internal configuration example of a solid-state imaging element as a first embodiment of the present technology.

FIG. 2 is an equivalent circuit diagram of a pixel.

FIG. 3 is a sectional view for describing a schematic structure of a pixel array unit.

FIG. 4 is a plan view of a pixel array unit as the first embodiment.

FIG. 5 is a sectional view for describing a schematic structure of the pixel array unit.

FIG. 6 is a plan view of a pixel array unit as a second embodiment.

FIG. 7 is a plan view of a pixel array unit as a third embodiment.

FIG. 8 is a plan view of a pixel array unit as a fourth embodiment.

FIG. 9 is a block diagram illustrating a configuration example of an imaging device to which a solid-state imaging element as an embodiment is applied.

### MODE FOR CARRYING OUT THE INVENTION

Hereinafter, embodiments will be described in the following order.
<1. First Embodiment>
[1-1. Overall configuration of solid-state imaging element]
[1-2. Circuit configuration of pixel]
[1-3. Structure of pixel array unit]
[1-4. Structure of inter-pixel isolator and arrangement of filters as first embodiment]
<2. Second Embodiment>
<3. Third Embodiment>
<4. Fourth Embodiment<
<5. Imaging device>
<6. Modifications>
<7. Summary of embodiments>
<8. Present technology>

### 1. FIRST EMBODIMENT

### [1-1. Overall Configuration of Solid-State Imaging Element]

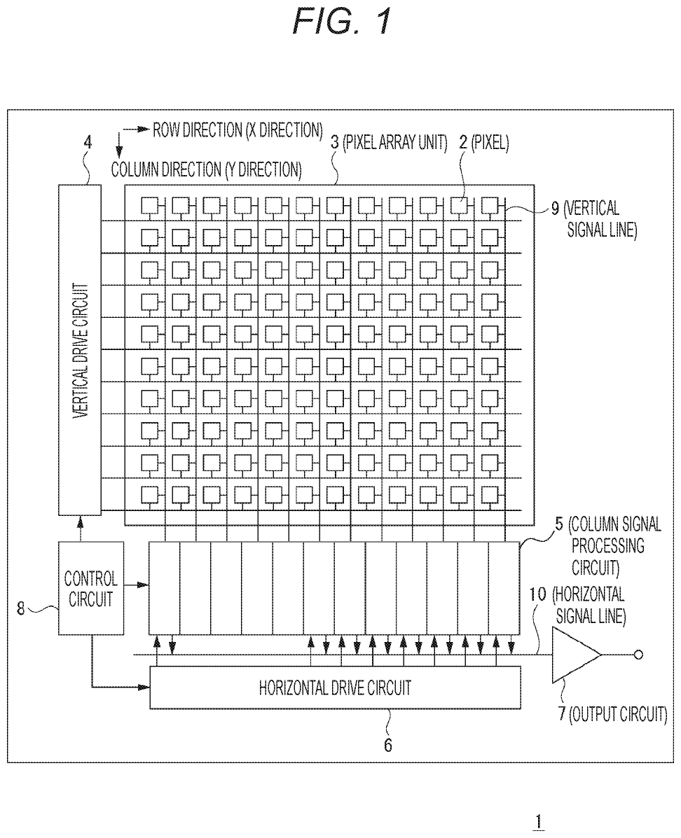

FIG. 1 is a block diagram illustrating an internal configuration example of a solid-state imaging element 1 as a first embodiment of the present technology.

The solid-state imaging element 1 according to the present embodiment includes a pixel array unit 3 in which a plurality of pixels 2 is formed, a vertical drive circuit 4, a column signal processing circuit 5, a horizontal drive circuit 6, an output circuit 7, a control circuit 8, and the like.

The pixel 2 includes a photoelectric converter and a plurality of pixel transistors. Note that a circuit configuration of the pixel 2 will be described later.

The pixel array unit 3 includes the plurality of pixels 2 arranged in each of a row direction and a column direction. Hereinafter, the row direction may be referred to as “X direction”, and the column direction may be referred to as “Y direction”.

The pixel array unit 3 includes an effective pixel region that actually receives light, amplifies signal charges generated by photoelectric conversion, and reads the signal charges to the column signal processing circuit 5, and a black reference pixel region (not shown) for outputting optical black serving as a reference of a black level. The black reference pixel region is usually formed on an outer periphery of the effective pixel region.

The control circuit 8 generates operation clocks, control signals, and the like of the vertical drive circuit 4, the column signal processing circuit 5, and the horizontal drive circuit 6 on the basis of a vertical synchronization signal, a horizontal synchronization signal, and a master clock, and outputs the operation clocks, the control signals, and the like to the vertical drive circuit 4, the column signal processing circuit 5, and the horizontal drive circuit 6.

The vertical drive circuit 4 includes, for example, a shift register, and selectively scans each pixel 2 of the pixel array unit 3 sequentially in a vertical direction row by row. Then, a pixel signal based on a signal charge obtained in accordance with the amount of received light in each pixel 2 is output to the column signal processing circuit 5 through a vertical signal line 9.

For example, the column signal processing circuit 5 is disposed for every column of the pixels 2, and performs signal processing such as noise removal and signal amplification on a signals output from the pixels 2 of one row on the basis of a signal from the black reference pixel region for every pixel column. A horizontal selection switch (not shown) is provided between an output stage of the column signal processing circuit 5 and the horizontal signal line 10.

The horizontal drive circuit 6 includes, for example, a shift register, sequentially selects each of the column signal processing circuits 5 by sequentially outputting horizontal scanning pulses, and causes each of the column signal processing circuits 5 to output a pixel signal to the horizontal signal line 10.

The output circuit 7 performs signal processing on the signals sequentially supplied from each of the column signal processing circuits 5 through the horizontal signal line 10, and outputs the processed signals as image signals.

### [1-2. Circuit Configuration of Pixel]

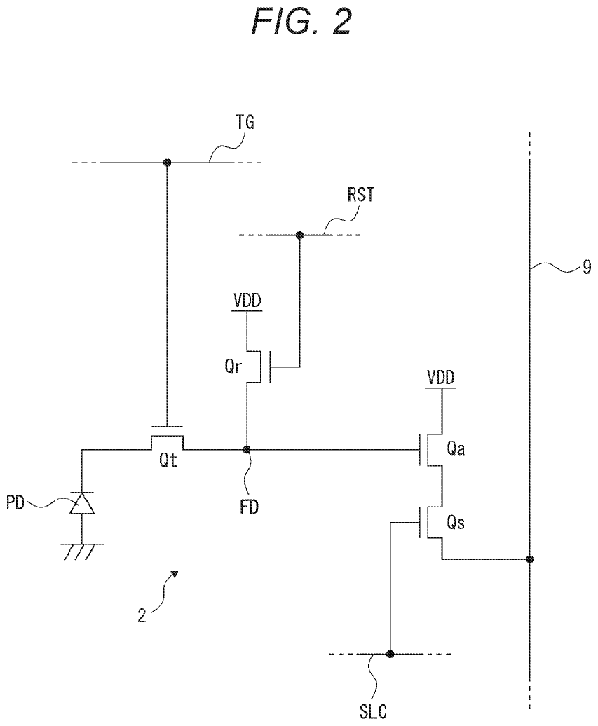

FIG. 2 is an equivalent circuit diagram of the pixel 2.

As illustrated in FIG. 2, the pixel 2 includes a photodiode PD as a photoelectric converter, and also includes a transfer transistor Qt, a floating diffusion (floating diffusion region) FD, a reset transistor Qr, an amplification transistor Qa, and a selection transistor Qs.

Here, in the present example, the various transistors included in the pixel 2 include, for example, metal-oxide-semiconductor field-effect transistors (MOSFETs).

The transfer transistor Qt has a gate connected to a supply line of a transfer drive signal TG, becomes conductive when the transfer drive signal TG is turned on, and transfers signal charge accumulated in the photodiode PD to the floating diffusion FD.

The floating diffusion FD is a charge holder that temporarily holds the charge transferred from the photodiode PD.

The reset transistor Qr has a gate connected to a supply line of a reset signal RST, becomes conductive when the reset signal RST is turned on, and resets a potential of the floating diffusion FD to a reference potential VDD.

The amplification transistor Qa has a source connected to the vertical signal line 9 via the selection transistor Qs, and a drain connected to the reference potential VDD (constant current source) to constitute a source follower circuit.

The selection transistor Qs is connected between the source of the amplification transistor Qa and the vertical signal line 9, and has a gate connected to a supply line of a selection signal SLC. The selection transistor Qs becomes conductive when the selection signal SLC is turned on, and outputs the charge held in the floating diffusion FD to the vertical signal line 9 via the amplification transistor Qa.

Here, the transfer drive signal TG, the reset signal RST, and the selection signal SLC are output from the vertical drive circuit 4 illustrated in FIG. 1.

To briefly describe an operation of the pixel 2 configured as described above, first, a charge reset operation (electronic shutter operation) for resetting the charge of the pixel 2 is performed before starting light reception. That is, the reset transistor Qr and the transfer transistor Qt are turned on (conductive), and accumulated charges in the photodiode PD and the floating diffusion FD are reset.

After resetting the accumulated charges, the reset transistor Qr and the transfer transistor Qt are turned off to start charge accumulation in the photodiode PD. Thereafter, when charge signals accumulated in the photodiode PD are read, the transfer transistor Qt is turned on, and the selection transistor Qs is turned on. Therefore, the charge signals are transferred from the photodiode PD to the floating diffusion FD, and the charge signals held in the floating diffusion FD are output to the vertical signal line 9 via the amplification transistor Qa.

### [1-3. Structure of Pixel Array Unit]

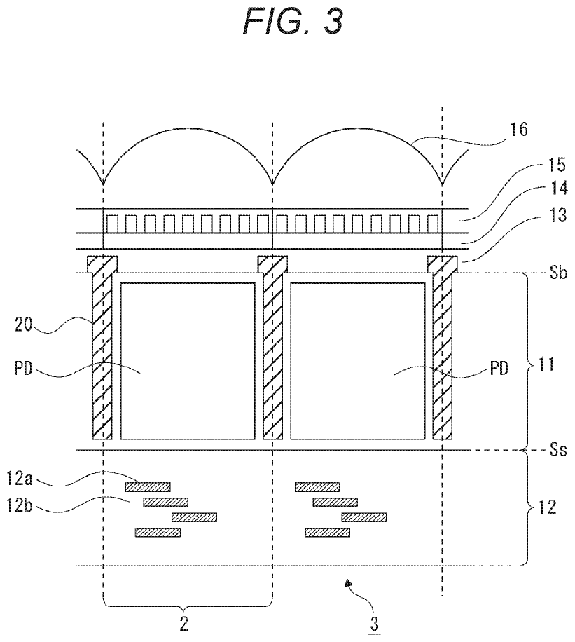

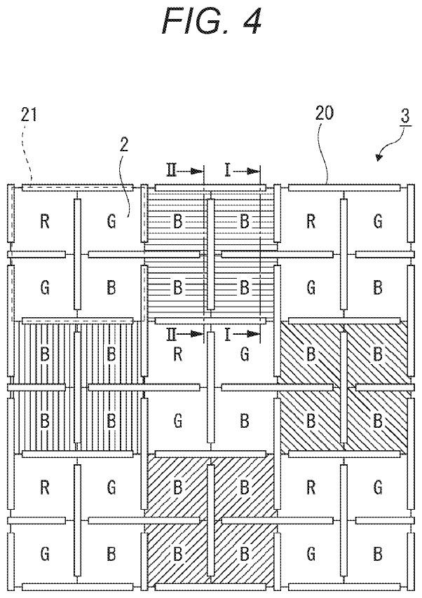

FIG. 3 is a sectional view for describing a schematic structure of the pixel array unit 3. Note that FIG. 3 is also a sectional view taken along line I-I in FIG. 4.

The solid-state imaging element 1 according to the present embodiment is a back-illuminated complementary metal oxide semiconductor (CMOS) image sensor. The “back surface” in this case is based on a front surface Ss and a back surface Sb of the semiconductor substrate 11 included in the pixel array unit 3.

As illustrated in FIG. 3, the pixel array unit 3 includes the semiconductor substrate 11 and a wiring layer 12 formed on a side close to the front surface Ss of the semiconductor substrate 11. On the back surface Sb of the semiconductor substrate 11, a planarization film 13, a color filter 14, a polarizing filter 15, and a microlens (on-chip lens) 16 are stacked in this order.

Note that, although the above-described pixel transistors (transfer transistor Qt, reset transistor Qr, amplification transistor Qa, and selection transistor Qs) are also formed in each pixel 2, these pixel transistors are not shown in FIG. 3. Here, conductors functioning as electrodes (each of the gate, drain, and source electrodes) of the pixel transistors are formed in the wiring layer 12 near the front surface Ss of the semiconductor substrate 11.

The semiconductor substrate 11 includes, for example, silicon (Si), and is formed with a thickness of, for example, about 1 μm to 6 μm. In the semiconductor substrate 11, the photodiode PD as photoelectric converter is formed in a region of each pixel 2.

The planarization film 13 is formed on the semiconductor substrate 11, which planarizes a surface of a side close to the back surface Sb of the semiconductor substrate 11. As a material of the planarization film 13, for example, an organic material such as resin can be used.

The color filter 14 is a filter that is formed on the planarization film 13 and transmits incident light of a predetermined wavelength band for every pixel 2. Examples of the filter here include a filter that transmits red (R) light, green (G) light, or blue (B) light, a filter that transmits infrared light, and the like.

The polarizing filter 15 is a filter that is formed on the color filter 14 and transmits light with a predetermined polarization direction for every pixel 2, that is, the polarizing filter 15 is a filter having a predetermined polarization transmission axis. The polarizing filter 15 includes, for example, a wire grid. The wire grid is configured by arranging a plurality of strip-shaped conductors at a predetermined pitch.

Note that the arrangement of the color filter 14 and the polarizing filter 15 will be described later in detail.

A microlens 16 is formed for every pixel 2 on the polarizing filter 15. In the microlens 16, incident light is condensed, and the condensed light is efficiently incident on the photodiode PD via the polarizing filter 15 and the color filter 14.

The wiring layer 12 is formed on the side close to the front surface Ss of the semiconductor substrate 11, and includes a plurality of layers of wirings 12a stacked with an interlayer insulating film 12b interposed therebetween. The pixel transistors are driven via the wirings 12a formed in the wiring layer 12.

Furthermore, in the pixel array unit 3 according to the present embodiment, an inter-pixel isolator 20 that isolates adjacent pixels 2 is formed. As exemplified in the plan view of FIG. 4, the inter-pixel isolator 20 is formed to isolate each pixel 2.

The inter-pixel isolator 20 can reduce crosstalk between adjacent pixels 2. Here, the crosstalk includes electrical crosstalk and optical crosstalk.

The electrical crosstalk refers to movement of charges between adjacent pixels 2. The optical crosstalk refers to leakage of incident light between adjacent pixels 2.

Here, the inter-pixel isolator 20 is formed as a reverse trench isolation (RTI). The RTI is a trench isolation generated by forming a groove extending toward the front surface Ss by cutting the semiconductor substrate 11 from the back surface Sb.

Here, in this example, a groove for isolation in the semiconductor substrate 11 is referred to as “trench”.

In this example, the inter-pixel isolator 20 is formed by reversed deep trench isolation (RDTI). The RDTI is a trench generated by forming a groove that does not penetrate the semiconductor substrate 11 in a thickness direction among the RTIs, and is formed from the back surface Sb at a predetermined depth that does not reach the front surface Ss.

Note that in a case where a trench is formed in the semiconductor substrate 11, a width of the trench tends to gradually decrease toward a progressing direction of cutting. Therefore, in a case where the trench is formed from the back surface Sb as in the RDTI, the inter-pixel isolator 20 has a feature that a width is narrower on the side close to the front surface Ss than on the side close to the back surface Sb.

### [1-4. Structure of Inter-Pixel Isolator and Arrangement of Filters as First Embodiment]

FIG. 4 is a plan view of the pixel array unit 3 as the first embodiment. Note that in FIG. 4, characters “R”, “G”, and “B” indicated in each pixel 2 represent types of color filters 14 disposed in the pixel 2. Specifically, the pixels 2 in which “R”, “G”, and “B” are indicated represent the pixels 2 in which the color filters 14 that transmit red light, green light, and blue light are disposed, respectively.

Furthermore, in FIG. 4, hatching indicated in each pixel 2 represent the type of the polarizing filter 15 disposed in the pixel 2. Specifically, the pixel 2 with hatching parallel to the left and right in the drawing represents a pixel in which the polarizing filter 15 that transmits light with a polarization direction of 0° is disposed. In addition, the pixel 2 indicated by hatching extending from the upper left to the lower right in the drawing represents a pixel in which the polarizing filter 15 that transmits light with a polarization direction of 45° is disposed. Furthermore, the pixel 2 with hatching parallel to the upper and lower sides in the drawing represents a pixel in which the polarizing filter 15 that transmits light with a polarization direction of 90° is disposed. In addition, the pixel 2 indicated by hatching extending from the upper right to the lower left in the drawing represents a pixel in which the polarizing filter 15 that transmits light with a polarization direction of 135° is disposed.

Therefore, there are provided four types of polarizing filters 15 having different polarization transmission axes (polarization axes) by 45°.

In the pixel array unit 3, four pixels 2 in two rows and two columns are configured as a set of pixel units 21, and the color filter 14 and the polarizing filter 15 are disposed in a predetermined pattern for every pixel unit 21.

For example, in FIG. 4, the pixel unit 21 in the upper left stage includes the pixels 2 in which color filters 14 of “R”, “G”, and “B” are arranged in a Bayer array. Furthermore, the polarizing filter 15 is not disposed in the pixels 2 of the pixel unit 21.

Then, the pixel units 21 including the pixels 2 in which the color filters 14 are arranged in the Bayer array are disposed in a staggered manner so as to be diagonally adjacent to each other.

Furthermore, the pixel unit 21 in the upper stage of the center is configured by four pixels 2 in which the color filter 14 of “B” and the polarizing filter 15 that transmits light with a polarization direction of 0° are disposed.

In addition, the pixel unit 21 diagonally disposed in the lower right direction with respect to the pixel unit 21 in the upper stage of the center, that is, the pixel unit 21 in the right middle stage is configured by the four pixels 2 in which the color filter 14 of “B” and the polarizing filter 15 that transmits light with a polarization direction of 45° are disposed.

In addition, the pixel unit 21 diagonally disposed in the lower left direction with respect to the pixel unit 21 in the upper stage of the center, that is, the pixel unit 21 in the middle left stage is configured by the four pixels 2 in which the color filter 14 of “B” and the polarizing filter 15 that transmits light with a polarization direction of 90° are disposed.

In addition, the pixel unit 21 disposed one unit apart in the downward direction from the pixel unit 21 in the upper stage of the center, that is, the pixel unit 21 in the lower stage in the center is configured by four pixels 2 in which the color filter 14 of “B” and the polarizing filter 15 that transmits light with a polarization direction of 135° are disposed.

As described above, for example, in the pixel unit 21 (adjacent pixels 2) in which the polarizing filter 15 is disposed, four pixels 2 of the filters (color filter 14 and polarizing filter 15) having the same light transmission characteristic are disposed side by side. Note that the light transmission characteristic determines a characteristic of transmitted light, such as a wavelength band or a polarization direction of transmitted light.

The inter-pixel isolator 20 is formed along the row direction and the column direction between the pixels 2. In addition, the inter-pixel isolators 20 are formed so as not to intersect each other.

For example, in FIG. 4, in the pixel unit 21 in the upper stage of the center, the inter-pixel isolator 20 extending across the two pixels 2 and not reaching each corner is formed on the upper side of the two pixels 2 in the upper stage. In addition, in this pixel unit 21, the inter-pixel isolator 20 extending across the two pixels 2 and not reaching each corner is formed on the lower side of the two pixels 2 in the lower stage.

Furthermore, in the pixel unit 21, the inter-pixel isolators 20 are formed so as to extend in the column direction in the center and not to be in contact with the upper and lower inter-pixel isolators 20. Furthermore, in the pixel unit 21, the inter-pixel isolators 20 are formed so as to extend in the row direction at the center and not to be in contact with the inter-pixel isolator 20 in the center.

As described above, as for the inter-pixel isolators 20, only the inter-pixel isolator 20 extending in one direction of the row direction or the column direction is formed at a cross portion where four pixels 2 are in contact, and the inter-pixel isolator 20 extending in the other direction is not formed. That is, the inter-pixel isolators 20 are formed so as not to intersect each other. As a result, in the pixel array unit 3, it is possible to reduce differences in the depth of the trench due to intersection of the inter-pixel isolators 20, and it is possible to reduce a process load.

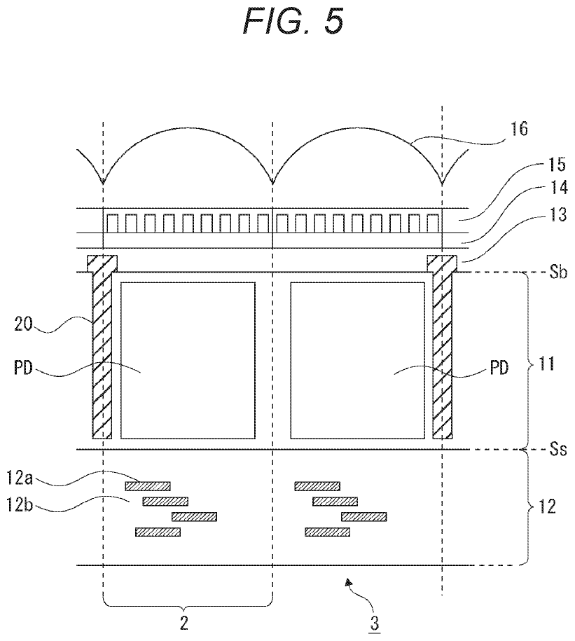

FIG. 5 is a sectional view for describing a schematic structure of the pixel array unit 3. Note that FIG. 5 is also a sectional view taken along line II-II in FIG. 4.

As illustrated in FIG. 4, since the inter-pixel isolators 20 are formed so as not to intersect at the cross portion where the four pixels 2 are in contact, there is a portion where no inter-pixel isolator 20 is formed between the adjacent pixels 2.

As illustrated in FIG. 5 which is a sectional view taken along line II-II in FIG. 4, the photodiodes PD of the adjacent pixels 2 are in contact with each other in the portion where no inter-pixel isolator 20 is formed between the adjacent pixels 2.

Therefore, charges move in the portion where no inter-pixel isolator 20 is formed, and thus, electrical crosstalk may occur. Then, such electrical crosstalk could deteriorate an extinction ratio, which is an important characteristic in the solid-state imaging element 1 including the polarizing filter 15. Note that the extinction ratio is a ratio for removing light with a polarization direction different from the target polarization direction.

Therefore, in the pixel array unit 3 according to the first embodiment, the polarizing filter 15 having the same polarization direction is disposed between the adjacent pixels 2, that is, for every pixel unit 21. As a result, in a portion where no inter-pixel isolator 20 is formed, even if charges move (even if electrical crosstalk occurs), the charges are based on incident light with the same polarization direction, and thus, the deterioration of the extinction ratio can be reduced.

Furthermore, the color filter 14 of “B” is disposed in the pixel 2 in which the polarizing filter 15 is disposed. In the pixel in which the color filter 14 of “B” is disposed, since the blue light passes through the color filter 14, photoelectric conversion is performed near the back surface Sb of the semiconductor substrate 11. Therefore, the charges generated by the photoelectric conversion are likely to move to the adjacent pixel 2.

However, in the pixel array unit 3 according to the first embodiment, even between the pixels 2 in which the color filter 14 of “B” is disposed, the polarizing filter 15 having the same polarization transmission axis is disposed, and thus, the deterioration of the extinction ratio can be reduced.

Furthermore, in the pixel array unit 3, the polarizing filter 15 is not disposed in the pixel unit 21 adjacent in the row direction or the column direction to the pixel unit 21 in which the polarizing filter 15 is disposed. Therefore, the pixel units 21 in which the polarizing filter 15 having a different polarization transmission axis is disposed are not disposed adjacent to each other in the row direction or the column direction. As a result, in the pixel array unit 3, it is possible to further reduce the deterioration of the extinction ratio.

Furthermore, the polarizing filter 15 having a different polarization transmission axis is disposed between the pixel units 21 diagonally adjacent to each other. However, the inter-pixel isolators 20 are disposed in the row direction or the column direction between the diagonally adjacent pixels 2 in which the polarizing filter 15 having a different polarization transmission axis is disposed. Therefore, in the pixel array unit 3, it is possible to further reduce the deterioration of the extinction ratio between such pixels 2 diagonally adjacent to each other.

### 2. SECOND EMBODIMENT

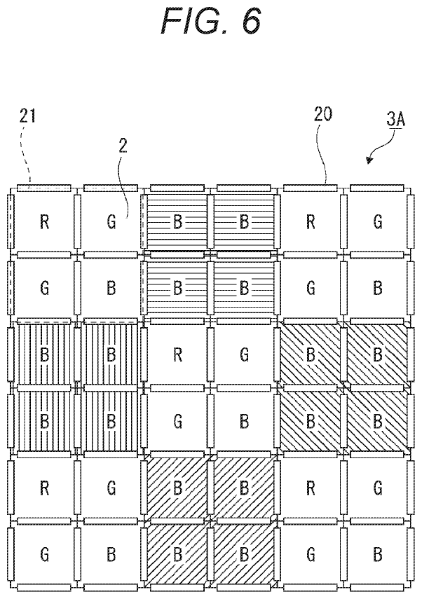

Next, a second embodiment will be described with reference to FIG. 6.

Note that, in the following description, the same reference signs are given to portions similar to those already described, and description thereof will be omitted.

FIG. 6 is a plan view of a pixel array unit 3A as the second embodiment. The pixel array unit 3A according to the second embodiment is different from the pixel array unit 3 in the location where the inter-pixel isolator 20 is formed, and the arrangement of the color filter 14 and the polarizing filter 15 is the same. Therefore, the arrangement of the color filter 14 and the polarizing filter 15 will not be described.

The inter-pixel isolator 20 according to the second embodiment is formed on each of the upper, lower, left, and right sides of each pixel 2 except for the cross portion. In other words, the inter-pixel isolator 20 is formed in the row direction and the column direction except for the cross portion.

Therefore, as compared with the pixel array unit 3, there is a portion where no inter-pixel isolator 20 is formed between the pixels 2 adjacent in the row direction or the column direction, and there is also a portion where no inter-pixel isolator 20 is formed between the pixels 2 diagonally disposed.

However, between the pixels 2 diagonally disposed, the charges move less than between the pixels 2 disposed adjacent to each other in the row direction or the column direction. Furthermore, in the pixel unit 21, the polarizing filter 15 having the same polarization direction is also disposed between the pixels 2 diagonally disposed. Therefore, in the pixel array unit 3A, it is possible to reduce the deterioration of the extinction ratio.

### 3. THIRD EMBODIMENT

A third embodiment relates to a variation of the arrangement of the color filters 14.

Note that, in the following description, the same reference signs are given to portions similar to those already described, and description thereof will be omitted. Furthermore, in the third embodiment, the arrangement of the inter-pixel isolators 20 according to the second embodiment will be described as an example, but the inter-pixel isolators 20 may be disposed as in the first embodiment.

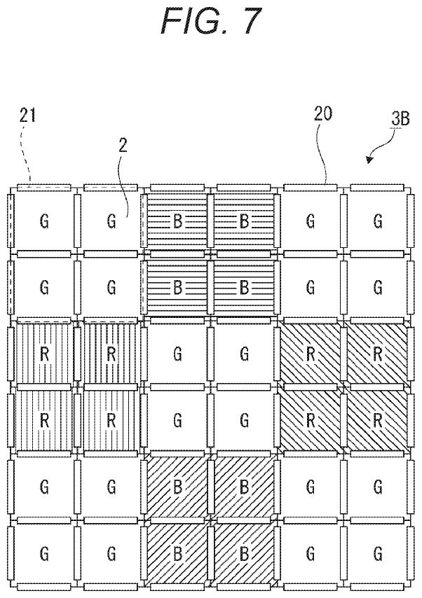

FIG. 7 is a plan view of a pixel array unit 3B as the third embodiment. The pixel array unit 3A according to the third embodiment is different from the pixel array unit 3 in the arrangement of the color filters 14, and the arrangement of the polarizing filters 15 is the same.

In the third embodiment, the pixel unit 21 in the upper left stage includes the pixels 2 in which the color filters 14 of “G” are disposed. The pixel unit 21 in the upper stage of the center includes the pixels 2 in which the color filters 14 of “B” are disposed. The pixel unit 21 in the upper right stage includes the pixels 2 in which the color filters 14 of “G” are disposed.

In addition, the pixel unit 21 in the left middle stage includes the pixels 2 in which the color filters 14 of “R” are disposed. The pixel unit 21 in the middle stage of the center includes the pixels 2 in which the color filters 14 of “G” are disposed. The pixel unit 21 in the right middle stage includes the pixels 2 in which the color filters 14 of “R” are disposed.

In addition, the pixel unit 21 in the lower left stage includes the pixels 2 in which the color filters 14 of “G” are disposed. The pixel unit 21 in the lower stage of the center includes the pixels 2 in which the color filters 14 of “B” are disposed. The pixel unit 21 in the lower right stage includes the pixels 2 in which the color filters 14 of “G” are disposed.

As described above, in the pixel array unit 3B according to the third embodiment, the color filters 14 are arranged in the Bayer array in units of pixel units 21.

Furthermore, similarly to the first embodiment, the pixel unit 21 at the center in the upper stage includes the pixels 2 in which the polarizing filters 15 that transmit light with a polarization direction of 0° are disposed. Furthermore, the pixel unit 21 in the right middle stage includes the pixels 2 in which the polarizing filters 15 that transmit light with a polarization direction of 45° are disposed. The pixel unit 21 in the left middle stage in the upper stage includes the pixels 2 in which the polarizing filters 15 that transmit light with a polarization direction of 90° are disposed. The pixel unit 21 in the lower stage of the center includes the pixels 2 in which the polarizing filters 15 that transmit light with a polarization direction of 135° are disposed.

As described above, in the third embodiment, the color filters 14 are arranged in the Bayer array in units of pixel units 21, and the polarizing filters 15 having a different polarization direction are arranged in a staggered manner in units of pixel units 21.

In such a pixel array unit 3B according to the third embodiment, similarly to the first embodiment, the polarizing filter 15 having the same polarization direction is disposed between the adjacent pixels 2, that is, for every pixel unit 21. As a result, even if charges move (even if electrical crosstalk occurs) in a portion where no inter-pixel isolator 20 is formed, the charges are based on incident light with the same polarization direction, and thus, the deterioration of the extinction ratio can be reduced.

### 4. FOURTH EMBODIMENT

A fourth embodiment relates to a variation of the arrangement of the color filters 14 and the polarizing filters 15.

Note that, in the following description, the same reference signs are given to portions similar to those already described, and description thereof will be omitted. Furthermore, in the third embodiment, the arrangement of the inter-pixel isolators 20 according to the second embodiment will be described as an example, but the inter-pixel isolators 20 may be disposed as in the first embodiment.

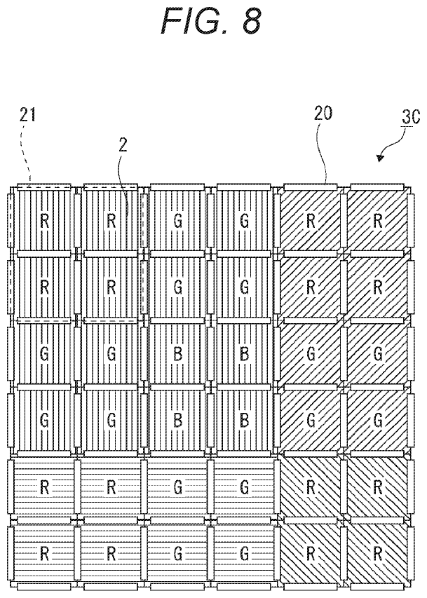

FIG. 8 is a plan view of a pixel array unit 3C as the fourth embodiment. In the pixel array unit 3C according to the fourth embodiment, the arrangement of the color filter 14 and the polarizing filter 15 is the same as in the pixel array unit 3.

In the pixel array unit 3C according to the fourth embodiment, similarly to the pixel array unit 3B according to the third embodiment, the color filters 14 are arranged in the Bayer array in units of pixel units 21.

Furthermore, the pixel units 21 at the upper left end, the upper stage of the center, the left middle stage, and the middle stage of the center are configured by the pixels 2 in which the polarizing filters 15 that transmit light with a polarization direction of 90° are disposed. In addition, the pixel units 21 in the upper right stage and the right middle stage are configured by the pixels 2 in which the polarizing filters 15 that transmit light with a polarization direction of 135° are disposed. The pixel units 21 in the lower right stage are configured by the pixels 2 in which the polarizing filters 15 that transmit light with a polarization direction of 45° are disposed. The pixel units 21 in the lower stage of the center and the lower left stage are configured by the pixels 2 in which the polarizing filters 15 that transmit light with a polarization direction of 0° are disposed.

As described above, in the pixel array unit 3C, the polarizing filters 15 having the same polarization direction are disposed, and the pixel units 21 are arranged in the Bayer array, with the pixel units 21 in two rows and two columns as one unit.

In this arrangement, in the pixel array unit 3C, for the pixel units 21 in two rows and two columns, that is, the pixels 2 in four rows and four columns, the polarizing filter 15 having the same polarization direction is disposed. As a result, even if charges move (even if electrical crosstalk occurs) between these pixels 2, the charges are based on incident light with the same polarization direction, and thus, the deterioration of the extinction ratio can be reduced.

### 5. IMAGING DEVICE

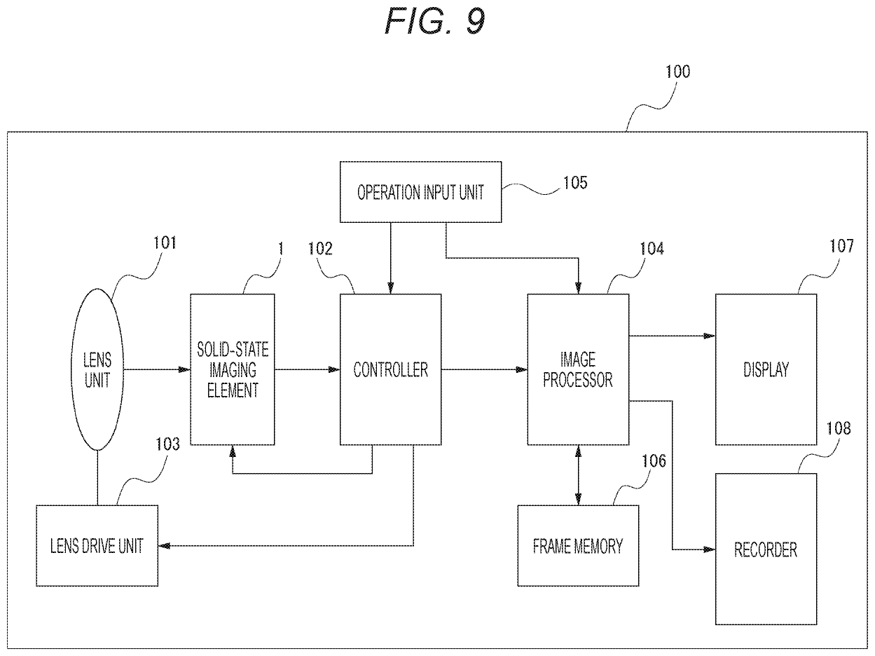

FIG. 9 is a block diagram illustrating a configuration example of an imaging device 100 to which the solid-state imaging element 1 as an embodiment is applied.

As illustrated in FIG. 9, the imaging device 100 includes the solid-state imaging element 1, a lens unit 101, a controller 102, a lens drive unit 103, an image processor 104, an operation input unit 105, a frame memory 106, a display 107, and a recorder 108.

The lens unit 101 includes, for example, a lens such as a cover lens and a focus lens, a shutter, an aperture mechanism, and the like, and is configured to guide light (incident light) from a subject to a light receiving surface of the solid-state imaging element 1.

The controller 102 includes, for example, a microcomputer including a central processing unit (CPU), a read only memory (ROM), and a random access memory (RAN).

The ROM of the controller 102 stores an operating system (OS) for the CPU to control each unit, an application program for various operations, firmware, and the like. The RAM of the controller 102 is used for temporary storage of data, programs, and the like as a work area at the time of various types of data processing of the CPU.

The controller 102 performs overall control of the imaging device 100 by the CPU executing a program stored in the ROM or the like.

For example, the controller 102 controls the shutter speed of the solid-state imaging element 1 and instructs the image processor 104 to perform various types of signal processing. Furthermore, the controller 102 controls the operation of each necessary unit with respect to an imaging operation or a recording operation according to a user's operation on the operation input unit 105, a reproduction operation of a recorded image file, a user interface operation, and the like. Moreover, the controller 102 also performs control regarding focus, aperture adjustment, and the like in the lens unit 101.

The lens drive unit 103 drives the lens unit 101 on the basis of control of the controller 102. The lens drive unit 103 can drive the lens unit 101 by changing the position of the lens unit 101 by using a built-in motor.

The image processor 104 processes an image signal generated by the solid-state imaging element 1. This processing includes, for example, demosaicing of generating an image signal of a lacking color among the image signals corresponding to red, green, and blue for each pixel, noise reduction of removing noise of the image signal, encoding of the image signal and the like. The image processor 104 can be configured by, for example, a DSP.

In addition, the image processor 104 executes depth mask generation processing of generating a depth map and normal map generation processing of generating a normal map on the basis of the image signal generated by the pixel 2 provided with the polarizing filter 15. Note that the above processing, which are known processing, will not be described in detail.

The operation input unit 105 receives an operation input from a user of the imaging device 100. As the operation input unit 105, for example, a push button or a touch panel can be used. The operation input received by the operation input unit 105 is transmitted to the controller 102 and the image processor 104. Thereafter, processing according to the operation input, for example, processing such as imaging of the subject is started.

The frame memory 106 is a memory that stores a frame, which is the image signal for one screen. The frame memory 106 is controlled by the image processor 104 and holds the frame in the course of the image processing.

The display 107 displays an image processed by the image processor 104. As the display 107, for example, a liquid crystal panel can be used.

The recorder 108 records the image processed by the image processor 104. As the recorder 108, for example, a memory card or a hard disk can be used.

### 6. MODIFICATIONS

Note that the embodiments are not limited to the specific examples described above and may be configured as various modification examples.

For example, the arrangement of the color filter 14 and the polarizing filter 15 in the first to fourth embodiments described above is an example, and it is sufficient that filter having the same light transmission characteristic is disposed at least between the plurality of adjacent pixels 2.

Furthermore, the formation of the inter-pixel isolators 20 in the first to fourth embodiments described above is an example, and at least the inter-pixel isolators 20 is only required to be formed without intersecting each other.

### 7. SUMMARY OF EMBODIMENTS

As described above, a solid-state imaging element 1 according to the embodiment includes a pixel array unit 3 in which a plurality of pixels 2 each having a photoelectric converter (photodiode PD) is arranged in each of a row direction and a column direction, in which the pixel array unit includes an inter-pixel isolator 20 that isolates the plurality of pixels adjacent to each other, each of the plurality of pixels includes a filter (color filter 14, polarizing filter 15) having a predetermined light transmission characteristic, the inter-pixel isolator is formed without intersecting the inter-pixel isolator, and the filter having the same light transmission characteristic is disposed between the plurality of pixels adjacent to each other.

As a result, even if crosstalk occurs in a portion provided with no inter-pixel isolator between pixels in which filter having the same light transmission characteristic is disposed, charges based on light transmitted through the filter having the same light transmission characteristic move.

In addition, since the inter-pixel isolator is formed without intersecting the inter-pixel isolator, it is not necessary to consider the depth of an intersecting portion, wafer warpage hardly occurs, and the process load at the time of manufacturing can be reduced.

Therefore, degradation of the pixel signal can be suppressed while reducing the process load.

Conceivably, in the solid-state imaging element according to the embodiment described above, the filter includes a polarizing filter 15 that transmits incident light with a specific polarization direction and causes the incident light to be incident on the photoelectric converter, and the polarizing filter having the same direction of a polarization transmission axis is disposed between the plurality of pixels adjacent to each other.

As a result, even if electrical crosstalk occurs in a portion provided with no inter-pixel isolator, the charges are based on light with the same polarization direction, and thus, the deterioration of the extinction ratio can be reduced.

Therefore, the degradation of the pixel signal can be suppressed by reducing the deterioration of the extinction ratio.

Conceivably, in the solid-state imaging element according to the embodiment described above, the filter includes the color filter 14 that transmits incident light of a specific wavelength band and causes the incident light to be incident on the photoelectric converter, and the color filter having the same wavelength band to be transmitted is disposed between the plurality of pixels adjacent to each other.

As a result, even if electrical crosstalk occurs in a portion provided with no inter-pixel isolator, the charges are based on light with the same wavelength band, and thus, color mixing can be reduced.

Therefore, the degradation of the pixel signal can be suppressed by reducing the color mixing.

Conceivably, in the solid-state imaging element according to the embodiment described above, the filter includes a polarizing filter that transmits incident light with a specific polarization direction and causes the incident light to be incident on the photoelectric converter, and a color filter that transmits incident light of a specific wavelength band and causes the incident light to be incident on the photoelectric converter, and the polarizing filter having the same direction of a polarization transmission axis and the color filter having the same wavelength band to be transmitted are disposed between the plurality of pixels adjacent to each other.

As a result, even if electrical crosstalk occurs in a portion provided with no inter-pixel isolator, the charges are based on light with the same polarization direction and the same wavelength band, and thus, the deterioration of the extinction ratio and the degradation of the color mixing can be reduced.

Therefore, the degradation of the pixel signal can be suppressed by reducing the deterioration of the extinction ratio and the color mixing.

Conceivably, in the solid-state imaging element according to the embodiment described above, the inter-pixel isolator includes a trench isolation formed at a depth not penetrating a semiconductor substrate 11 on which the photoelectric converter is formed.

As a result, since the inter-pixel isolators do not intersect each other to be cut deeply, it is not necessary to consider these influences, and a process load at the time of forming trench isolation can be reduced.

Conceivably, in the solid-state imaging element according to the embodiment described above, the inter-pixel isolator includes a trench isolation formed from a back surface of the semiconductor substrate.

Here, an insulating film may be formed on the inter-pixel isolator together with the back surface of the semiconductor substrate. In such a case, by forming the trench isolation from the back surface of the semiconductor substrate, the process load at the time of the formation of the trench isolation can be reduced.

Conceivably, in the solid-state imaging element according to the embodiment described above, the inter-pixel isolator is formed in one direction of a row direction or a column direction at a cross portion of the pixels adjacent to each other in the row direction and the column direction.

It is therefore possible to reduce crosstalk between the pixels diagonally adjacent to each other.

As a result, the degradation of the pixel signal between the pixels diagonally adjacent to each other can be suppressed.

Conceivably, in the solid-state imaging element according to the embodiment described above, the inter-pixel isolator is not formed at the cross portion of the pixels adjacent to each other in the row direction and the column direction.

As a result, since the inter-pixel isolators are not formed in all the cross portions, the process load at the time of the formation of the inter-pixel isolators can be reduced.

Conceivably, the solid-state imaging element according to the embodiment described above includes a plurality of pixel blocks each including the plurality of pixels adjacent to each other in a row direction and a column direction, in which the polarizing filter is disposed on one side between the pixel blocks adjacent to each other in the row direction or the column direction.

As a result, the charges based on light with a different polarization direction cause no crosstalk between the pixel blocks adjacent to each other, and the deterioration of the pixel signal can be suppressed.

Conceivably, the solid-state imaging element according to the embodiment described above includes a plurality of pixel blocks each including the plurality of pixels adjacent to each other in a row direction and a column direction, in which the polarizing filter having the same direction of a polarization transmission axis is disposed between the pixel blocks adjacent to each other in the row direction or the column direction.

As a result, even if electrical crosstalk occurs in a portion provided with no inter-pixel isolator between the pixel blocks, the charges are based on light with the same polarization direction, and thus, the deterioration of the extinction ratio can be reduced.

Therefore, the degradation of the pixel signal can be suppressed by reducing the deterioration of the extinction ratio.

As described above, an imaging device 100 according to an embodiment includes a solid-state imaging element including a pixel array unit in which a plurality of pixels each having a photoelectric converter is arranged in a row direction and a column direction, and an image processor that processes an image signal generated by the solid-state imaging element, in which the pixel array unit includes an inter-pixel isolator that isolates the plurality of pixels adjacent to each other, each of the plurality of pixels includes a filter having a predetermined light transmission characteristic, the inter-pixel isolator is formed without intersecting with the inter-pixel isolator, and the filter having the same light transmission characteristic is disposed between the plurality of pixels adjacent to each other.

In this imaging device, functions and effects similar to the functions and effects of the solid-state imaging element can be also exhibited.

Note that the effects described in the present specification are merely examples and are not limited, and other effects may be provided.

### 8. PRESENT TECHNOLOGY

Note that the present technology can also employ the following configurations.

(1)

A solid-state imaging element including
a pixel array unit in which a plurality of pixels each having a photoelectric converter is arranged in each of a row direction and a column direction, in which
the pixel array unit includes an inter-pixel isolator that isolates the plurality of pixels adjacent to each other,
each of the plurality of pixels includes a filter having a predetermined light transmission characteristic,
the inter-pixel isolator is formed without intersecting the inter-pixel isolator, and
the filter having a same light transmission characteristic is disposed between the plurality of pixels adjacent to each other.

(2)

The solid-state imaging element according to (1), in which
the filter includes a polarizing filter that transmits incident light with a specific polarization direction and causes the incident light to be incident on the photoelectric converter, and
the polarizing filter having a same direction of a polarization transmission axis is disposed between the plurality of pixels adjacent to each other.

(3)

The solid-state imaging element according to (1) or (2), in which
the filter includes a color filter that transmits incident light of a specific wavelength band and causes the incident light to be incident on the photoelectric converter, and
the color filter having a same wavelength band to be transmitted is disposed between the plurality of pixels adjacent to each other.

(4)

The solid-state imaging element according to any of (1) to (3), in which
the filter includes
a polarizing filter that transmits incident light with a specific polarization direction and causes the incident light to be incident on the photoelectric converter, and
a color filter that transmits incident light of a specific wavelength band and causes the incident light to be incident on the photoelectric converter, and
the polarizing filter having the same direction of the polarization transmission axis and the color filter having a same wavelength band to be transmitted are disposed between the plurality of pixels adjacent to each other.

(5)

The solid-state imaging element according to any of (1) to (4), in which
the inter-pixel isolator includes a trench isolation formed at a depth not penetrating a semiconductor substrate on which the photoelectric converter is formed.

(6)

The solid-state imaging element according to (5), in which
the inter-pixel isolator includes a trench isolation formed from a back surface of the semiconductor substrate.

(7)

The solid-state imaging element according to any of (1) to (6), in which
the inter-pixel isolator is formed in one direction of a row direction or a column direction at a cross portion of the pixels adjacent to each other in the row direction and the column direction.

(8)

The solid-state imaging element according to any of (1) to (6), in which
the inter-pixel isolator is not formed at a cross portion of the pixels adjacent to each other in the row direction and the column direction.

(9)

The solid-state imaging element according to (2), further including
a plurality of pixel blocks each including the plurality of pixels adjacent to each other in a row direction and a column direction, in which
the polarizing filter is disposed on one side between the pixel blocks adjacent to each other in the row direction or the column direction.

(10)

The solid-state imaging element according to claim (2) or (4), further including
a plurality of pixel blocks each including a plurality of the pixels adjacent to each other in a row direction and a column direction, in which
the polarizing filter having the same direction of the polarization transmission axis is disposed between the pixel blocks adjacent to each other in the row direction or the column direction.

(11)

An imaging device including:
a solid-state imaging element including a pixel array unit in which a plurality of pixels each having a photoelectric converter is arranged in a row direction and a column direction; and
an image processor that processes an image signal generated by the solid-state imaging element, in which
the pixel array unit includes an inter-pixel isolator that isolates the plurality of pixels adjacent to each other,
each of the plurality of pixels includes a filter having a predetermined light transmission characteristic,
the inter-pixel isolator is formed without intersecting with the inter-pixel isolator, and
the filter having a same light transmission characteristic is disposed between the plurality of pixels adjacent to each other.

### REFERENCE SIGNS LIST

1 Solid-state imaging element
2 Pixel
3, 3A, 3B, 3C Pixel array unit
11 Semiconductor substrate
14 Color filter
15 Polarizing filter
20 Inter-pixel isolator
21 Pixel unit
100 Imaging device
104 Image processor

1. A solid-state imaging element comprising
a pixel array unit in which a plurality of pixels each having a photoelectric converter is arranged in each of a row direction and a column direction, wherein
the pixel array unit includes an inter-pixel isolator that isolates the plurality of pixels adjacent to each other,
each of the plurality of pixels includes a filter having a predetermined light transmission characteristic,
the inter-pixel isolator is formed without intersecting the inter-pixel isolator, and
the filter having a same light transmission characteristic is disposed between the plurality of pixels adjacent to each other.

2. The solid-state imaging element according to claim 1, wherein
the filter includes a polarizing filter that transmits incident light with a specific polarization direction and causes the incident light to be incident on the photoelectric converter, and
the polarizing filter having a same direction of a polarization transmission axis is disposed between the plurality of pixels adjacent to each other.

3. The solid-state imaging element according to claim 1, wherein
the filter includes a color filter that transmits incident light of a specific wavelength band and causes the incident light to be incident on the photoelectric converter, and
the color filter having a same wavelength band to be transmitted is disposed between the plurality of pixels adjacent to each other.

4. The solid-state imaging element according to claim 1, wherein
the filter includes
a polarizing filter that transmits incident light with a specific polarization direction and causes the incident light to be incident on the photoelectric converter, and
a color filter that transmits incident light of a specific wavelength band and causes the incident light to be incident on the photoelectric converter, and
the polarizing filter having a same direction of a polarization transmission axis and the color filter having a same wavelength band to be transmitted are disposed between the plurality of pixels adjacent to each other.

5. The solid-state imaging element according to claim 1, wherein
the inter-pixel isolator includes a trench isolation formed at a depth not penetrating a semiconductor substrate on which the photoelectric converter is formed.

6. The solid-state imaging element according to claim 5, wherein
the inter-pixel isolator includes a trench isolation formed from a back surface of the semiconductor substrate.

7. The solid-state imaging element according to claim 1, wherein
the inter-pixel isolator is formed in one direction of a row direction or a column direction at a cross portion of the pixels adjacent to each other in the row direction and the column direction.

8. The solid-state imaging element according to claim 1, wherein
the inter-pixel isolator is not formed at a cross portion of the pixels adjacent to each other in the row direction and the column direction.

9. The solid-state imaging element according to claim 2, further comprising
a plurality of pixel blocks each including the plurality of pixels adjacent to each other in a row direction and a column direction, wherein
the polarizing filter is disposed on one side between the pixel blocks adjacent to each other in the row direction or the column direction.

10. The solid-state imaging element according to claim 2, further comprising
a plurality of pixel blocks each including a plurality of the pixels adjacent to each other in a row direction and a column direction, wherein
the polarizing filter having the same direction of the polarization transmission axis is disposed between the pixel blocks adjacent to each other in the row direction or the column direction.

11. An imaging device comprising:
a solid-state imaging element including a pixel array unit in which a plurality of pixels each having a photoelectric converter is arranged in a row direction and a column direction; and
an image processor that processes an image signal generated by the solid-state imaging element, wherein
the pixel array unit includes an inter-pixel isolator that isolates the plurality of pixels adjacent to each other,
each of the plurality of pixels includes a filter having a predetermined light transmission characteristic,
the inter-pixel isolator is formed without intersecting with the inter-pixel isolator, and
the filter having a same light transmission characteristic is disposed between the plurality of pixels adjacent to each other.
